(19) United States
(12) Patent Application Publication
(10) Pub. No.: US 2026/0370194 A1
(43) Pub. Date: Nov. 19, 2026

(54) LOW NOISE AMPLIFIER

(71) Applicant: Cirrus Logic International Semiconductor Ltd., Edinburgh (GB)

(72) Inventor: Paul WILSON, Edinburgh (GB)

(73) Assignee: Cirrus Logic International Semiconductor Ltd., Edinburgh (GB)

(21) Appl. No.: 19/135,678

(22) PCT Filed: Dec. 13, 2023
(86) PCT No.: PCT/GB2023/053214

§ 371 Date: Jun. 4, 2025

Related U.S. Application Data
(60) Provisional application No. 63/443,091, filed on Feb. 3, 2023.

(30) Foreign Application Priority Data
Apr. 24, 2023 (GB) 2305973.6

(51) Int. Cl. H03F 3/04

(52) U.S. Cl. CPC H03F 3/04; H03F 2200/294

(57) ABSTRACT

Bias circuitry for a capacitive transducer comprising: a high impedance element (Rpd) for coupling between one terminal of the capacitive transducer and a reference voltage (Vref); and unity gain circuitry coupled in parallel with at least two back-to-back diodes, wherein, in use of the bias circuitry, one terminal of the coupled unity gain circuitry and the at least two back-to-back diodes is coupled to the one terminal of the capacitive transducer.

### FIELD OF THE INVENTION

The field of representative embodiments of this disclosure relates to methods, apparatuses and/or implementations concerning and/or relating to amplification of signals from capacitive transducers. Applications include, but are not limited to, those concerning the amplification of signals from MEMS capacitive transducers such as MEMS microphones.

### BACKGROUND

Consumer electronics devices are continually getting smaller and, with advances in technology, are gaining ever-increasing performance and functionality. This is clearly evident in the technology used in consumer electronic products and especially, but not exclusively, portable products such as portable communications devices, mobile phones, audio players, video players, personal digital assistants (PDAs), wearable devices, smart glasses, smart watches, listening devices, earphones, earbuds, hearing aids, mobile computing platforms such as laptop computers or tablets and/or games devices. Requirements of the mobile phone industry for example, are driving the components to become smaller with higher functionality, lower power consumption and reduced cost. Micro-electromechanical-system (MEMS) transducers, such as MEMS microphones are finding application in many of these devices. There is therefore also a continual drive to reduce the size and cost of such MEMS microphones and to minimize the area and space taken up with such transducers, for example to enable the use of MEMS transducers that are suitable for embedding in earbuds for noise cancellation or other requirements for acoustic-electrical feedback such as speaker linearization.

However, the desire for reduction in physical size conflicts with the desire to provide better performance, for example regarding the level of the electronic noise floor and/or leakage currents. There may be no space available for off-chip capacitors or to provide dual-supplies to allow use of ground as a signal reference voltage or to decouple sensitive nodes with respect to ground. Also, system power budgets are progressively getting smaller, and lower power tends, thermodynamically, to imply higher circuit noise levels.

Embodiments of the present disclosure relate to methods, apparatus and/or implementations with improved noise performance, for instance to circuits in which any contribution to noise at an output node that arises due to noise on bias voltage references is at least partly reduced or even eliminated.

### SUMMARY

According to a first aspect, the invention provides circuitry for coupling to a capacitive transducer for compensating for a leakage current associated with the capacitive transducer, the circuitry comprising: a unity gain positive feedback loop comprising: unity gain circuitry having an input coupled to an input node of the circuitry; and a first set of back-to-back coupled diodes coupled between an output of the unity gain circuitry and the input node; and a negative feedback loop from an output node of the circuitry to the input node, wherein the negative feedback loop comprises a leakage current compensating amplifier and a second set of back-to-back coupled diodes coupled between an input and an output of the leakage current compensating amplifier, and wherein a property, characteristic or parameter of the second set of back-to-back coupled diodes is substantially similar to the first set of back-to-back coupled diodes such that, in use of the circuitry, the first and second sets of back-to-back coupled diodes exhibit the same or similar current and impedance values.

The negative feedback loop may comprise a proportional-integral (PI) controller; and a leakage current compensating amplifier.

The PI controller may be configured to receive an output voltage of the circuitry and a reference voltage; and the leakage current compensating amplifier may be configured to receive an output signal from the PI controller.

The PI controller may comprise an integrator.

The PI controller may have a relatively high DC gain.

The negative feedback loop may comprise a low pass filter coupled between an output node of the circuitry and a first input of the PI controller.

A parameter, property or characteristic of the low pass filter may be adjustable.

The circuitry may further comprise a variable resistance coupled between an output of the PI controller and an input of the leakage current compensating amplifier for changing a bandwidth mode of the circuitry between a normal bandwidth mode and a high bandwidth mode.

The capacitive transducer may comprise a MEMS transducer, for example.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the invention will now be described, strictly by way of example only, with reference to the accompanying drawings, of which:

FIG. 1a is a schematic representation of bootstrapping circuitry that may be used in a MEMS application such as a MEMS capacitive microphone or other MEMS capacitive transducer;

FIG. 1b is a schematic representation of alternative bootstrapping circuitry;

FIG. 2a is a schematic representation of further alternative bootstrapping circuitry that may be used in a MEMS application;

FIG. 2b is a schematic representation of further alternative bootstrapping circuitry;

FIG. 3 is a representative logarithmic scale graph of gain versus frequency for the circuitry illustrated in FIGS. 2a and 2b;

FIG. 4 is a schematic representation of bootstrapping circuitry with a leakage current compensating gain that may be used in a MEMS application;

FIG. 5 is a representative logarithmic scale graph of gain versus frequency for the circuitry illustrated in FIG. 4;

FIG. 6a is more detailed schematic representation of an embodiment of the bootstrapping circuitry illustrated in FIG. 4;

FIG. 6b is a schematic representation of alternative bootstrapping circuitry;

FIG. 7 is a representative logarithmic scale graph of the total loop gain versus frequency for the arrangement of the circuitry illustrated in FIGS. 6a and 6b;

FIGS. 8a and 8b are generalised schematic representations of the bootstrapping circuitry of FIGS. 2a, 2b, 4, 6a and 6b;

FIGS. 9a and 9b are generalised schematic representations of the bootstrapping circuitry of FIGS. 2a, 2b, 4, 6a and 6b;

FIGS. 10a and 10a are generalised schematic representations of a mixed-signal (analog and digital) embodiment of the bootstrapping circuitry of FIGS. 2a, 2b, 4, 6a and 6b; and

FIG. 11 is a schematic representation of an embodiment of bootstrapping circuitry and amplifier circuitry for a differential MEMS transducer.

### DETAILED DESCRIPTION

The description below sets forth example embodiments according to this disclosure. Further example embodiments and implementations will be apparent to those having ordinary skill in the art. Further, those having ordinary skill in the art will recognize that various equivalent techniques may be applied in lieu of, or in conjunction with, the embodiments discussed below, and all such equivalents and combinations should be deemed as being encompassed by the present disclosure.

The impedance of a diode can be controlled by a DC current as determined by the formula Rdio=Vt/Id, where Rdio is a small signal impedance of the diode, Vt is a thermal voltage kT/q and Id is the diode DC current.

However, the linear signal range of a diode is too small for applications such as biasing an input of a low noise amplifier (LNA).

Bootstrapping techniques can advantageously be used to increase the linear signal range of a diode for applications such as LNA input bias.

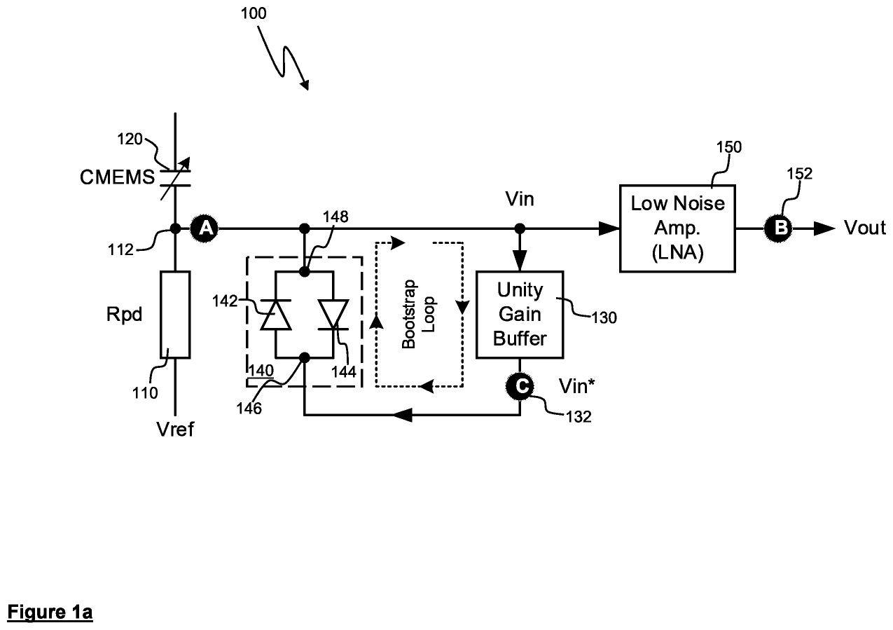

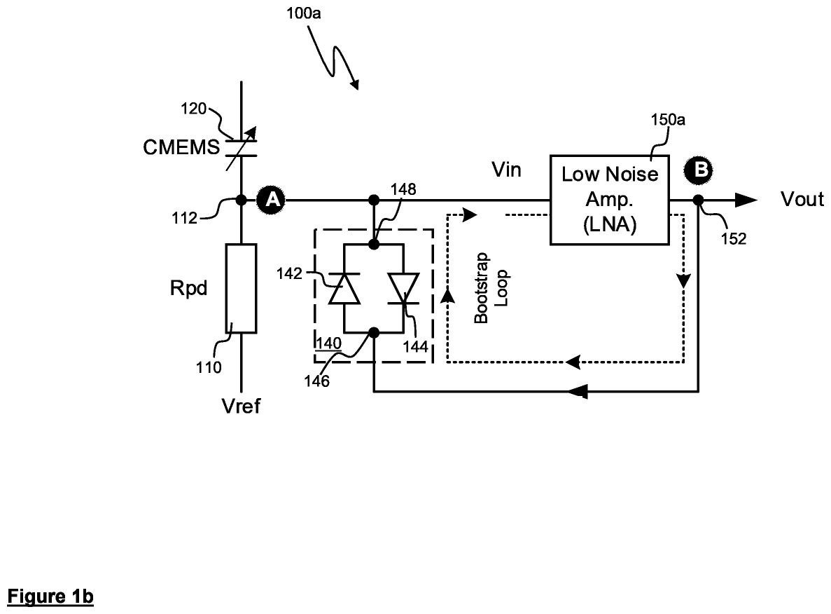

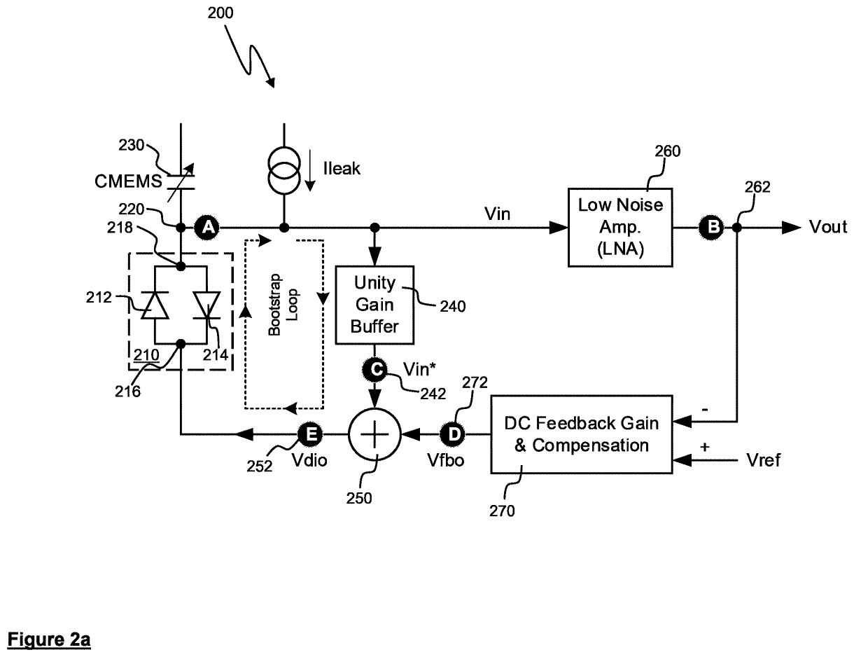

Referring first to FIG. 1a, bootstrapping circuitry that may be used in a MEMS (microelectromechanical system) application such as a MEMS capacitive microphone or other capacitive transducer is shown generally at 100.

The bootstrapping circuitry 100 in this example comprises a bias resistor 110 coupled in series between a first (input) node 112 (also labelled as node A in FIG. 1a) and a reference voltage supply node which supplies a reference Vref. The reference voltage Vref may be, for example, ground potential (Gnd). A capacitive transducer 120 (which may be a MEMS transducer, e.g. a MEMS microphone) is coupled to the first node 112.

The bias resistor 110 is a high impedance (high Z) element made up, for example, of a plurality of polysilicon diodes (also referred to as poly diodes). Each of these poly diodes may be in the form of PIN diode, which is a diode with a wide, undoped intrinsic semiconductor region between a p-type semiconductor and an n-type semiconductor region.

The bootstrapping circuitry 100 further includes a unity gain buffer 130 provided, having an input coupled to the first node 112 and an output coupled to an input of a back-to-back connected diode arrangement 140 at a third node 132 (also labelled as node C in FIG. 1a). The back-to-back connected diode arrangement 140 comprises a first diode 142 and a second diode 144. An anode of the first diode 142 is coupled to a cathode of the second diode 144 at a first diode coupling node 146 of the back-to-back connected diode arrangement 140, and a cathode of the first diode 142 is coupled to an anode of the second diode 144 at a second diode coupling node 148 of the back-to-back connected diode arrangement 140. This back-to-back connected diode arrangement 140 may also be referred to as an “anti-parallel diode connection” arrangement. The first diode coupling node 146 is coupled to the third node 132 (and thus to the output of the unity gain buffer 130) and the second diode coupling node 148 is coupled to the first node 112. This connection of the unity gain buffer 130 and the back-to-back (or anti-parallel) connected diode arrangement 140 provide a first positive feedback loop with a gain G of 1 (which may be referred to as a bootstrap loop) around the first node 112.

In the example shown in FIG. 1a, an input of a low noise amplifier (LNA) 150 is coupled to the first node 112 for receiving an input voltage Vin. An output of the LNA 150 is coupled to a second node 152 (also labelled as node B in FIG. 1a) for outputting an output voltage Vout.

The bootstrap loop formed of the unity gain amplifier 130 and the back-to-back (or anti-parallel) connected diode arrangement 140 eliminates, minimises or at least reduces any AC signal appearing across the back-to-back (or anti-parallel) connected diode arrangement 140. This bootstrap loop arrangement also increases the high impedance signal range of the back-to-back (or anti-parallel) connected diode arrangement 140 and reduces leakage current (Ileak) and/or the effects of leakage current.

It should be noted that if the circuitry represented in FIG. 1a is provided on an integrated circuit (IC), the back-to-back diodes may also be configured to have a secondary function as electrostatic discharge (ESD) diodes.

FIG. 1b is a schematic representation of alternative bootstrapping circuitry which is based on the bootstrapping circuitry 100 of FIG. 1a. This alternative bootstrapping circuitry, shown generally at 100a in FIG. 1b, includes a number of features in common with the bootstrapping circuitry 100 of FIG. 1a. Such common features are denoted by common reference numerals in FIGS. 1a and 1b and will not be described again in detail here, for the sake of clarity and brevity.

The bootstrapping circuitry 100a of FIG. 1b differs from the bootstrapping circuitry 100 of FIG. 1a, in that it does not include a unity-gain buffer. The first node 112 is coupled to an input of an LNA 150a, which may be a unity gain LNA. An output of the LNA 150a is coupled to the second node 152.

If the LNA 150a of FIG. 1b is a unity gain LNA, then the unity gain buffer 130 that is coupled between the first node 112 (node A) and the third node 132 (node C) in the bootstrapping circuitry 100 of FIG. 1a may be omitted, and the output voltage (Vout) of the unity gain LNA 150a may be applied to the first diode coupling node 146 of the back-to-back (or anti-parallel) connected diode arrangement 140 and hence to the anode of the first diode 142 and to the cathode of the second diode 144, as illustrated in FIG. 1b. Therefore, the back-to-back (or anti-parallel) connected diode arrangement 140 is coupled between the second node 152 (node B) and the first node 112 (node A). The principle described and illustrated in respect of FIG. 1b may be applied to all like embodiments herein disclosed.

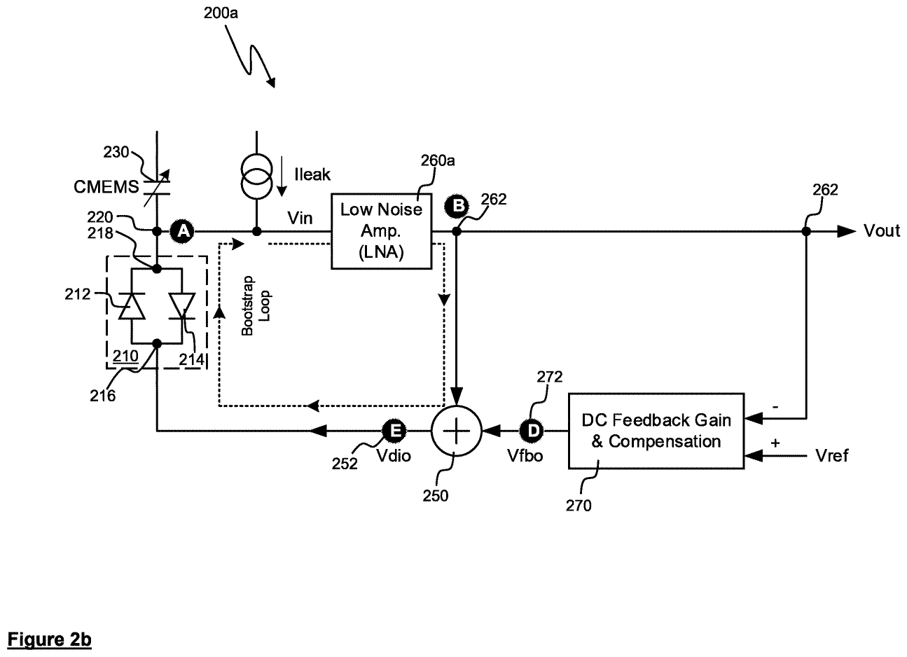

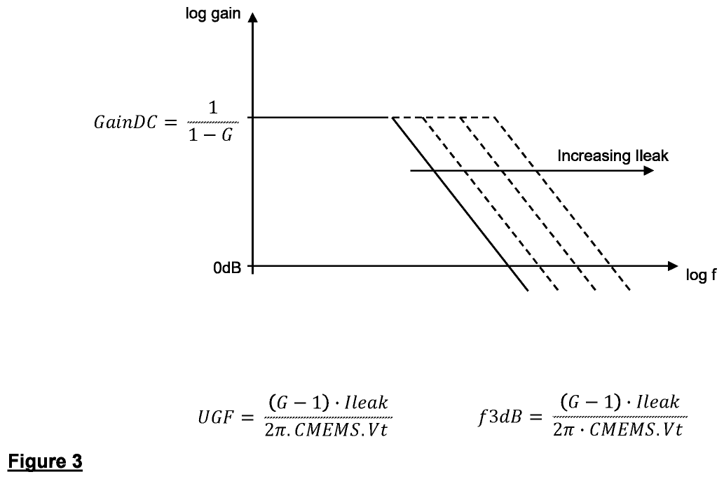

FIG. 2a is a schematic representation of further alternative bootstrapping circuitry for use, for example, in MEMS applications or other applications which use a capacitive transducer.

In this example the bootstrapping circuitry, shown generally at 200 in FIG. 2a, includes a back-to-back (or anti-parallel) diode connected arrangement 210 comprising a first diode 212 and a second diode 214. An anode of the first diode 212 is coupled to a cathode of the second diode 214 at a first diode coupling node 216 of the back-to-back (or anti-parallel) connected diode arrangement 210, and a cathode of the first diode 212 is coupled to an anode of the second diode 214 at a second diode coupling node 218 of the back-to-back connected (or anti-parallel) diode arrangement 210.

The second diode coupling node 218 is coupled to a first (input) node 220 of the bootstrapping circuitry 200 (which is also labelled as node A in FIG. 2a). A first terminal of a capacitive transducer 230 (which may be a MEMS transducer, e.g. a MEMS microphone) is also coupled to the first node 220.

An input of a unity gain buffer 240 is coupled to the first node 220. An output of the unity gain buffer 240 is coupled, at a second node 242 (labelled as node C in FIG. 2a) to a first input of summing circuitry 250, such that the summing circuitry 250 receives, at its first input, a voltage Vin* output by the unity gain buffer 240. An output of the summing circuitry 250 is coupled, at a third node 252 (also labelled as node E in FIG. 2a) to the first diode coupling node 216 of the back-to-back (or anti-parallel) diode connected arrangement 210.

The first (input) node 220 is also coupled to an input of an LNA 260, so as to supply an input voltage Vin to the input of the LNA 260. The LNA 260 supplies an output voltage VOut at an output node 262 (also labelled as node B in FIG. 2a).

The output node 262 is coupled to a first input of DC feedback gain and compensation circuitry 270. A second input of the DC feedback gain and compensation circuitry 270 receives a reference voltage Vref. An output of the DC feedback gain and compensation circuitry 270 is coupled, at a fourth node 272 (also labelled as node D in FIG. 2a) to a second input of the summing circuitry 250, and supplies a feedback voltage Vfbo to the second input of the summing circuitry 250.

Thus, the summing circuitry 250 receives the unity gain output buffer output voltage Vin* at its first input and the feedback voltage Vfbo at its second input, and outputs a summed voltage Vdio at its output, such that the summed voltage Vdio is received at the first diode coupling node 216 of the back-to-back diode (or anti-parallel) connected arrangement 210.

The connection of the unity gain buffer 240, summing circuitry 250 and the back-to-back (or anti-parallel) connected diode arrangement 210 provides a first feedback loop, in the form of a positive unity gain bootstrap loop, around the first node 220 (node A). The connection of the DC feedback gain and compensation circuitry 270, summing circuitry 250 and the back-to-back (or anti-parallel) connected diode arrangement 210 provides a second feedback loop from the output node 262 (node B) to the first node 220 (node A) in the form of a negative feedback loop.

The embodiment illustrated in FIG. 2a includes DC feedback so that the poly diode bias resistor 110 shown in the embodiments of FIGS. 1a and 1b can be eliminated.

The transfer function of the closed loop bootstrap loop from the fourth node 272 (node D) to the first node 220 (node A) is given by:

Vbp/Vfbo=1/(s·CMEMS·Rdio+(1−G)), where:
Vbp is a voltage at the first node 220,
Vfbo is the feedback voltage at the fourth node 272,
Rdio=Vt/Ileak,
G is the gain of the unity gain buffer 240,
Vt is the thermal voltage kT/q, and
Ileak represents the leakage current due to the MEMS transducer (CMEMS).

FIG. 2b is a schematic representation of alternative bootstrapping circuitry based on the bootstrapping circuitry 200 of FIG. 2a. This alternative bootstrapping circuitry, shown generally at 200a in FIG. 2b, includes a number of features in common with the bootstrapping circuitry 200 of FIG. 2a. Such common features are denoted by common reference numerals in FIGS. 2a and 2b and will not be described again in detail here, for the sake of clarity and brevity.

The bootstrapping circuitry 200a of FIG. 2b differs from the bootstrapping circuitry 200 of FIG. 2a in that it omits the unity gain buffer 240. In the example shown in FIG. 2b, an output of an LNA 260a (which has an input coupled to the first node 220, as in the example shown in FIG. 2a) is coupled to the first input of the summing circuitry 250, such that the output voltage Vdio output by the summing circuitry 250 is the sum of the output voltage Vout and the feedback voltage Vfbo output by the DC feedback gain and compensation circuitry 270.

As with the embodiment illustrated in FIG. 1b, if the LNA 260a illustrated in FIG. 2a is a unity gain LNA then the unity gain buffer 240 that is coupled between the first node 220 (node A) and the second node 242 (node C) in the example shown in FIG. 2a may be eliminated and the output voltage (Vout) of the unity gain LNA 260a may be coupled to the bottom first diode coupling node 216 of the back-to-back (or anti-parallel) connected diode arrangement 210 (and hence to the anode of the first diode 212 and to the cathode of the second diode 214) via the summing circuitry 250 as illustrated in FIG. 2b. Therefore, the back-to-back (or anti-parallel) connected diode arrangement 210 is coupled between the third node 252 (node) and the first node 220 (node A).

FIG. 3 illustrates a representative logarithmic scale graph of gain versus frequency for the arrangement of the circuitry illustrated in FIGS. 2a and 2b. As can be seen from FIG. 3, the unity gain frequency (UGF) bandwidth increases with an increase in Ileak.

A DC gain GainDC of the arrangement shown in FIG. 2a can be defined by the relationship

$$GainDC = \frac{1}{1 - G} ,$$

where G is a gain of the unity gain buffer 240.

A 3 dB frequency f3 dB of the arrangement shown in FIG. 2a can be defined by the relationship

$$f 3 dB = \frac{( G - 1 ) \cdot Ileak}{2 π \cdot CMEMS \cdot V t} ,$$

where Vt represents the thermal voltage kT/q, CMEMS is the capacitance of the capacitive transducer 230 and Ileak is the leakage current.

Unity gain frequency (UGF) is the frequency at which the gain of an amplifier is equal to unity (0 dB) and is represented by the x axis (log f) in FIG. 3. UGF can be defined by the relationship

$$UGF = \frac{G \cdot Ileak}{2 π \cdot CMEMS \cdot V t} .$$

By way of example, if the gain (G) of the unity gain buffer 240 is 0.99, the capacitance (CMEMS) of the capacitive transducer 230 is 1 pF, the leakage current (Ileak) is 1 fA and the resistance of the back-to-back (or anti-parallel) connected diode arrangement 210 is 26TΩ, this gives rise to a DC gain (GainDC) of 40 dB, and a unity gain frequency (UGF) of 6 mHz.

The arrangement of FIG. 2b may have a similar gain versus frequency characteristic, DC gain, 3 dB frequency and UGF as the arrangement of FIG. 2a.

It would be advantageous if the UGF bandwidth were independent of leakage current (Ileak) but unfortunately the UGF bandwidth is varies with leakage current according to the relationship UGF=G·Ileak/(2π·CMEMS·Vt).

In order to reduce the dependence of UGF bandwidth on leakage current (Ileak), a gain which is inversely proportional to the leakage current (Ileak) can be introduced into the DC feedback gain and compensation circuitry.

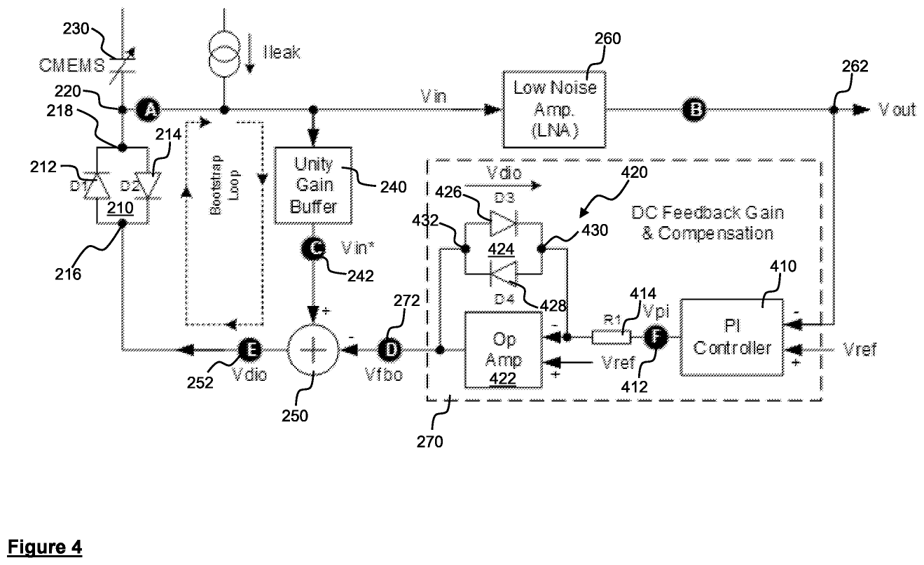

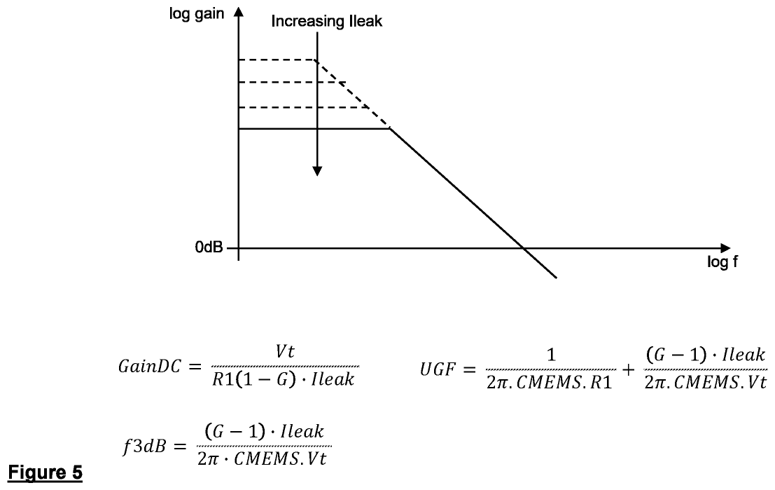

FIG. 4 is a schematic representation of bootstrapping circuitry with a leakage current compensating gain that may be used in a MEMS application or in another application that uses a capacitive transducer.

The arrangement shown in FIG. 4 is similar to the arrangement of FIG. 2a, and so features that are common to FIGS. 2a and 4 are denoted by common reference numerals and will not be described again in detail here, for the sake of clarity and brevity.

As shown in FIG. 4, the DC feedback gain and compensation circuitry 270 in this example comprises a proportional-integral (PI) controller 410 having a first input coupled to the output node 262 (node B) and a second input at which the reference voltage Vref is received. A PI controller output voltage Vpi is output at an output node 412 of the PI controller 410 (also labelled as node F in FIG. 4).

The DC feedback gain and compensation circuitry 270 further comprises a leakage current (Ileak) compensating gain amplifier 420 coupled between the output node 412 (node F) and a fourth node 272 (node D). The leakage current (Ileak) compensating gain amplifier 420 comprises an operational amplifier (op-amp) 422 and a back-to back (or anti-parallel) connected diode arrangement 424.

The back-to-back (or anti-parallel) connected diode arrangement 424 comprises first and second back-to-back connected diodes 426, 428 (also labelled as D3 and D4 in FIG. 4), which are the same as, or a close approximation to, the first and second back-to-back (or anti-parallel) connected diodes 212, 214 of the back-to-back (or anti-parallel) connected diode arrangement 210 that is coupled between the third node 252 (node E) and the first node 220 (node A)

The back-to-back (or anti-parallel) connected diode arrangement 424 of the DC feedback gain and compensation circuitry 270 is coupled across the operational amplifier 422, such that a first diode coupling node 430 (which couples the cathode of the first diode 426 to the anode of the second diode 428) is coupled to a first input of the op-amp 422 and a second diode coupling node 432 (which couples the anode of the first diode 426 to the cathode of the second diode 428) is coupled to an output of the op-amp 422.

A resistor 414 of resistance R1 is coupled between the output of the PI controller 410 and the first input of the op-amp 422. A second input of the op-amp 422 receives a reference voltage Vref.

Due to the structure and operation of the circuitry of FIG. 4, the voltage drop (Vdio) across the first and second diodes 212, 214 of the back-to-back (or anti-parallel) connected diode arrangement 210 is equal to the voltage drop (Vdio) across the first and second diodes 426, 428 of the back-to-back (or anti-parallel) connected diode arrangement 424 of the DC feedback gain and compensation circuitry 270, and therefore the back-to-back (or anti-parallel) connected diode arrangement 210 and the back-to-back (or anti-parallel) connected diode arrangement 424 of the DC feedback gain and compensation circuitry 270 exhibit the same, or nearly the same, current (Ileak) and impedance (Rdio) values.

Therefore, the leakage current (Ileak) compensating gain introduced by the DC feedback gain and compensation circuitry 270 can be expressed as:

Vfbo/Vpi=−Vt/(Ileak·R1),
where Vt is the thermal voltage kT/q.

Combining the gains gives:

Vbp/Vpi=−Rdio/(s·CMEMS·Rdio·R1+R1(1−G))

A DC gain GainDC of the arrangement shown in FIG. 4 can be defined by the relationship

$$GainDC = \frac{V t}{R 1 ( 1 - G ) \cdot Ileak} .$$

A 3 dB frequency f3 dB of the arrangement shown in FIG. 4 can be defined by the relationship

$$f 3 dB = \frac{( G - 1 ) \cdot Ileak}{2 π \cdot CMEMS \cdot V t} .$$

Unity gain frequency (UGF) is the frequency at which the gain of an amplifier is equal to unity (0 dB). UGF can be defined by the relationship

$$UGF = \frac{1}{2 π \cdot CMEMS \cdot R 1} + \frac{( G - 1 ) \cdot Ileak}{2 π \cdot CMEMS \cdot V t} .$$

Assuming G=1, the arrangement of FIG. 4 has:
a DC gain inversely proportional to the leakage current Ileak,
a 3 dB frequency f3 dB proportional to the leakage current Ileak, and
UGF independent of the leakage current Ileak (for G=1).

FIG. 5 is a representative logarithmic scale graph of gain versus frequency for the circuitry illustrated in FIG. 4. Unity gain frequency (UGF) is the frequency at which the gain of an amplifier is equal to unity (0 dB) and is represented by the x axis (log f) in FIG. 5. As can be seen from FIG. 5, the unity gain frequency (UGF) bandwidth does not change with a change of the leakage current Ileak.

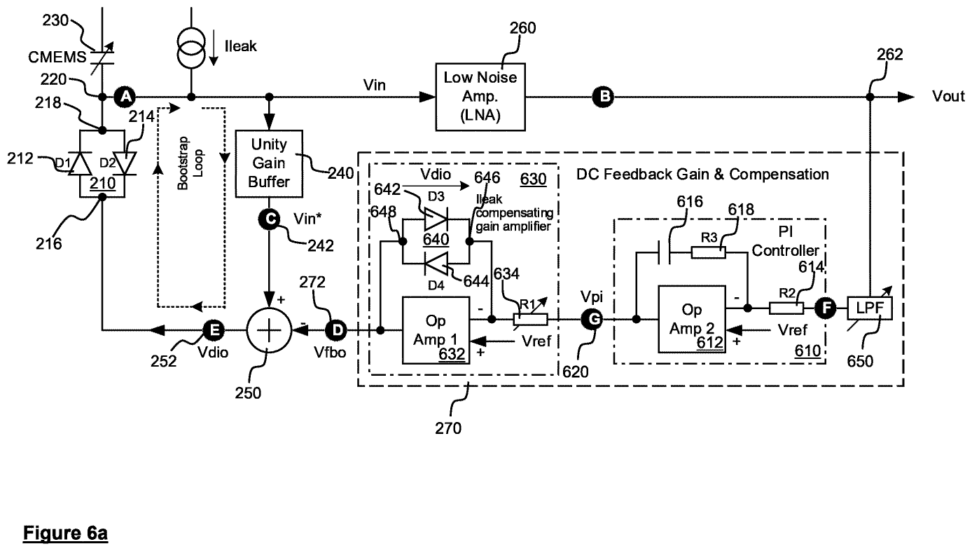

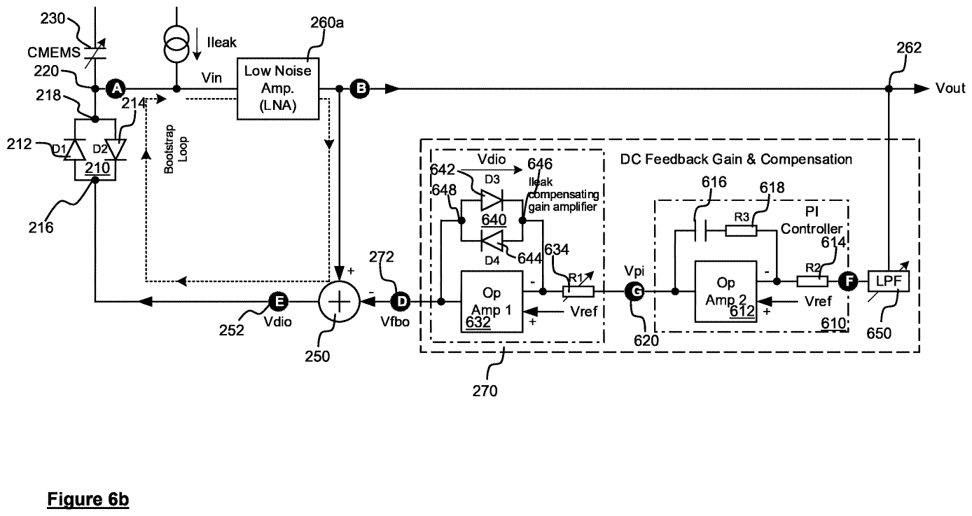

FIG. 6a is more detailed schematic representation of an embodiment of the bootstrapping circuitry illustrated in FIG. 4. The arrangement shown in FIG. 6a is similar to the arrangement of FIG. 4, and so features that are common to FIGS. 4 and 6a are denoted by common reference numerals and will not be described again in detail here, for the sake of clarity and brevity.

In order to force the output voltage (Vout) of the LNA at the output node 262 to a reference voltage Vref (which may be ground potential, Gnd, for example) to Vref, an integrator and compensation are used.

The integrator in the example of FIG. 6 is in the form of a PI controller 610 and compensation is in the form of a leakage current (Ileak) compensating gain amplifier 630.

The PI controller 610 in this example comprises an operational amplifier 612 having a first input that is coupled, via an input resistor 614, to the output node 262. A second input of the operational amplifier 612 receives a reference voltage Vref. An output voltage Vpi of the PI controller 610 is output at a PI controller output node 620. A feedback loop comprising a series combination of a capacitor 616 and a resistor 618 couples an output of the operational amplifier 612 to the first input of the operational amplifier 612.

The leakage current compensating gain amplifier 630 in this example comprises an operational amplifier 632 having a first input that is coupled, via an input variable resistance 634, to the output node 620 of the PI controller 610. A second input of the operational amplifier receives a reference voltage Vref. An output of the operational amplifier 632 is coupled to the fourth node 272.

The first input of the operational amplifier 632 is coupled to an output of the operational amplifier 632 by a back-to-back (or anti-parallel) connected diode arrangement 640, which comprises back-to-back (or anti-parallel) connected first and second diodes 642, 644 (labelled as D3 and D4 respectively in FIG. 6a). Thus, a first diode coupling node 646 of the back-to-back (or anti-parallel) connected diode arrangement 640 (which couples a cathode of the first diode 642 to an anode of the second diode 644) is coupled to the first input of the operational amplifier 632, and a second diode coupling node 648 (which couples an anode of the first diode 642 to a cathode of the second diode 644) is coupled to the output of the operational amplifier 632.

FIG. 6a also shows a variable low pass filter (LPF) 650 coupled between the output of the LNA (at the output node 262) an input of the PI controller 610 that is coupled, via the resistor 614, to the first input of the operational amplifier 612. As noted above, an input variable resistance 634 couples the output node 620 of the PI controller 610 to the first input of the operational amplifier 632 (which in the illustrated example is a negative or inverting input). The variable LPF 650 and the input variable resistance 634 will be described further below.

Adding the integrator and compensation makes the system illustrated in FIGS. 2, 4 and 6 a second order system. The PI controller 610 has a relatively high DC gain which is advantageous.

The transfer function of the PI controller 610 (i.e. the integrator), is given by:

Vpi/Vout=−s·C1·(R3+1)/s·C1·R2

FIG. 6b is a schematic representation of alternative bootstrapping circuitry based on the bootstrapping circuitry of FIG. 6a. The arrangement shown in FIG. 6b is similar to the arrangement of FIG. 6a, and so features that are common to FIGS. 6a and 6b are denoted by common reference numerals and will not be described again in detail here, for the sake of clarity and brevity.

As with the embodiment illustrated in FIG. 1b if the LNA 260 illustrated in FIG. 6a is a unity gain LNA then the unity gain buffer 240 that is coupled between the first node 220 (node A) and the second node 242 (node C) may be omitted and the output voltage (Vout) of the unity gain LNA may be coupled to the first diode coupling node 216 of the back-to-back (or anti-parallel) connected diode arrangement 210 (and thus to the anode of the first diode 212 and the cathode of the second diode 214) via the summing circuitry 250, as illustrated in FIG. 6b. Thus, in the arrangement shown in FIG. 6b, the back-to-back (or anti-parallel) connected diode arrangement 210 is coupled between the output of the summing circuitry 250 at the third node 252 (node E) and the first (input) node 220.

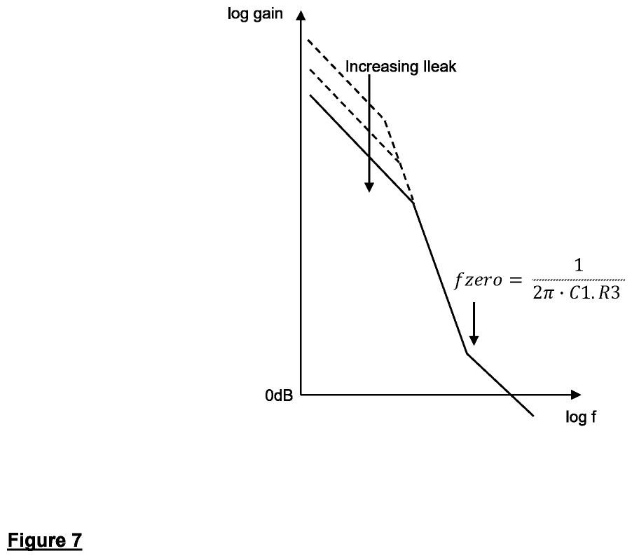

FIG. 7 is a representative logarithmic scale graph of the total loop gain versus frequency for the arrangement of the circuitry illustrated in FIGS. 6a and 6b. In the following discussion it is assumed that a gain G of the unity gain buffer 240 is equal to 1, and that a gain Glna of the low noise amplifier 260 is also equal to 1.

Unity gain frequency (UGF) is the frequency at which the gain of an amplifier is equal to unity (0 dB) and is represented by the x axis (log f) in FIG. 7.

A slew rate (SR) limit for the input voltage (Vin) to the LNA 260 on output node 262 (node B) settling is given by:

SR=V/T=I/C=Idio/CMEMS,
where Idio=Vpi/R1 and R1 is the resistance of the input variable resistance 634.

If it is assumed that the voltage Vpi output by the PI controller 610 (i.e. the integrator) is limited by supply rails, say +/−1V for example, then the slew rate limit SR of the voltage Vin is given by:

SR=Vpimax/CMEMS/R1, in volts per second

In order for Vin to settle fast, the resistance R1 at the input of the leakage current compensating gain amplifier 630 (i.e. the resistance of the input variable resistance 634) needs to reduce.

One or more higher order poles may be needed to attenuate the audio band to reduce the signal range needed at the outputs of the operational amplifier 632 of the leakage current compensating gain amplifier 630 and the operational amplifier 612 of the PI controller 610. Adjusting the one or more higher order poles may be achieved by adjusting one or more values of one or more elements that make up the variable LPF 650 of FIG. 6a, as will be readily understood by one of ordinary skill in the art.

Therefore, higher order poles will need to track the UGF when changing bandwidth (BW) mode. The BW mode can be changed between modes 1 and 2 by changing the value of R1, as illustrated in Table 1.

Table 1 below illustrates the design parameters for a first, normal BW, mode and a second, high BW, mode. In Table 1, R1 is the resistance of the input variable resistance 634 of the leakage current compensating gain amplifier 630, R2 is the resistance of the input resistor 614 of the PI controller 610, R3 is the resistance of the resistor 618 in the feedback path of the operational amplifier 612 and C1 is the capacitance of the capacitor 616 of the feedback path of the operational amplifier 612.

TABLE 1

| | Mode 1 | Mode 2 |
|---|---|---|
| | (Normal BW) | (High BW) |
| Gain (G) | 0.99 | 0.99 |
| R1 (G ohms) | 1000 | 10 |
| R2 (G ohms) | 16000 | 16000 |
| R3 (G ohms) | 16000 | 16000 |
| C1 (pF) | 1 | 1 |

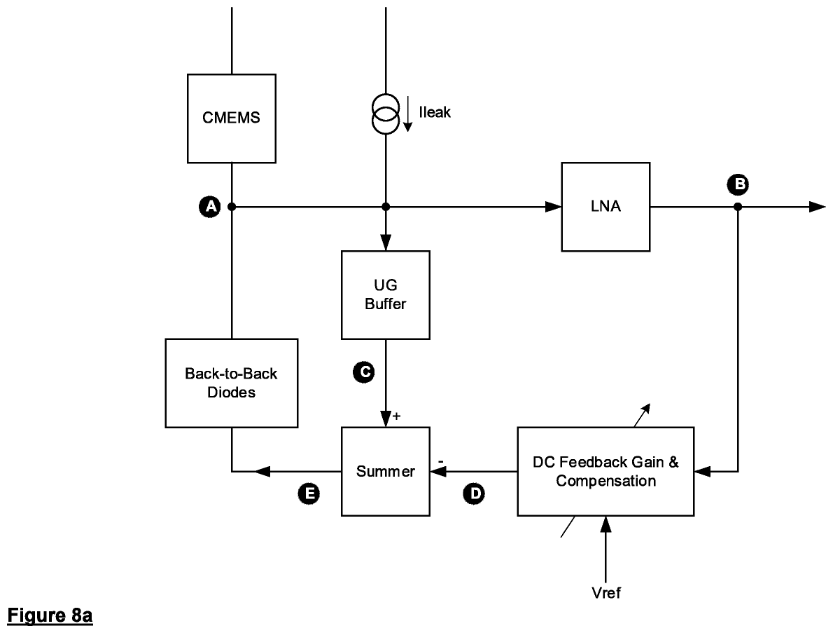

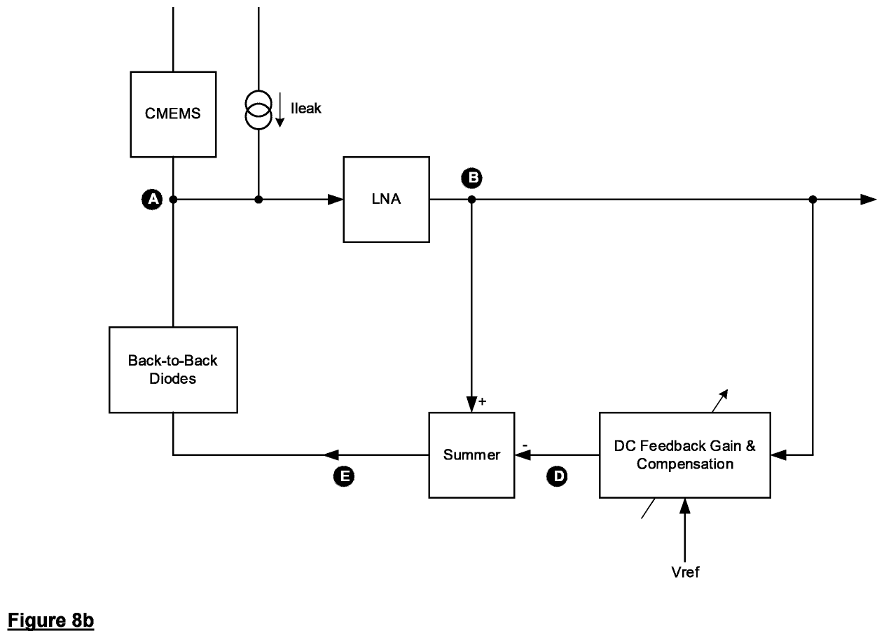

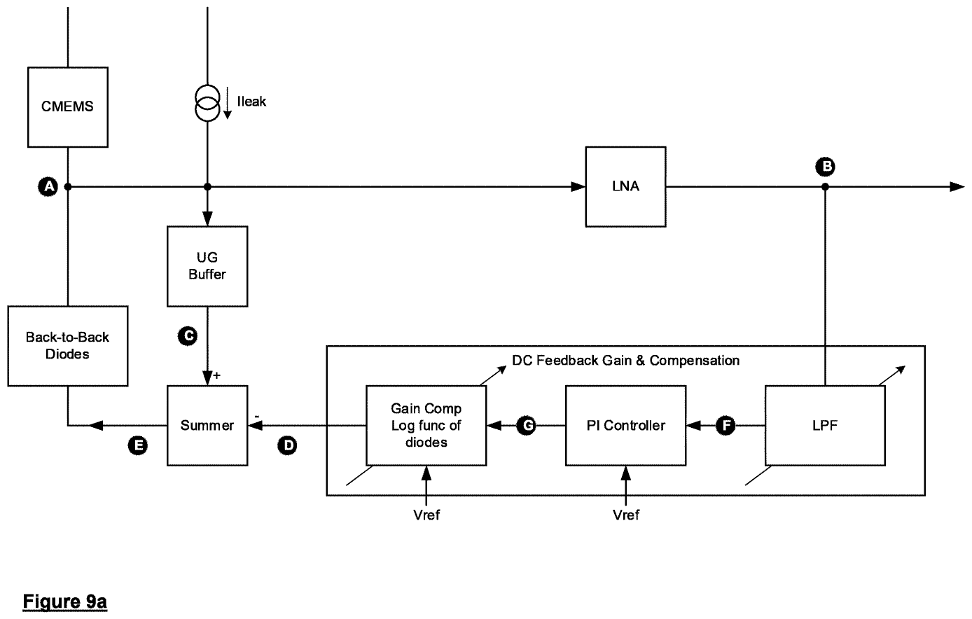

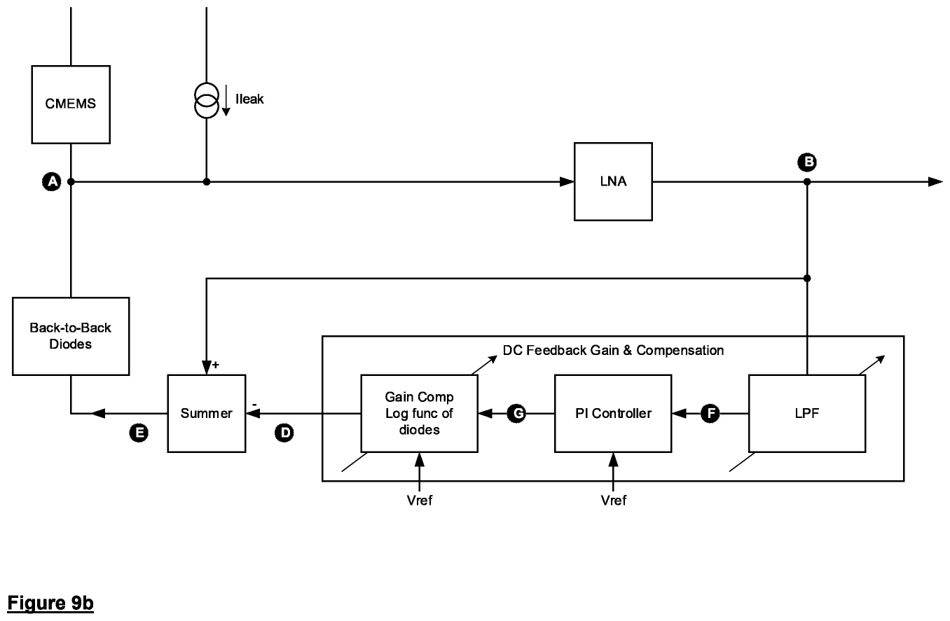

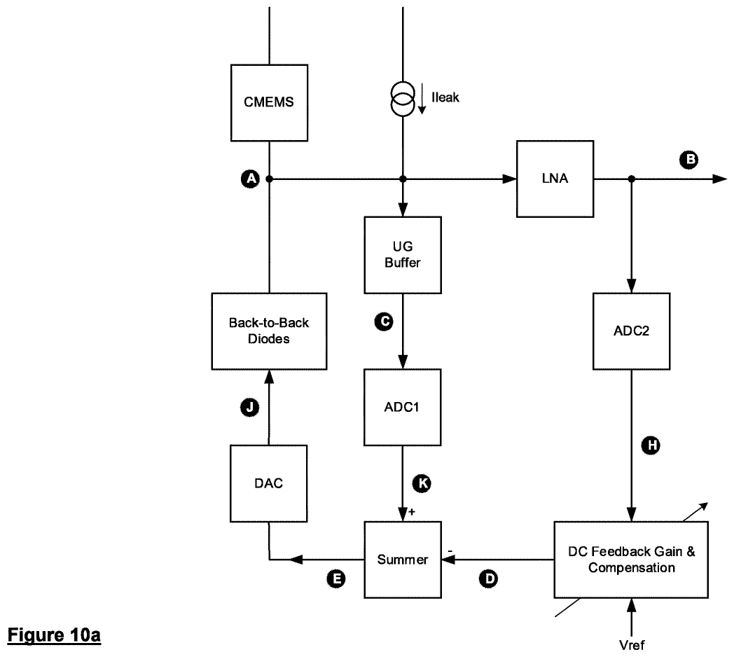

FIGS. 8a, 8b, 9a and 9b are generalised schematic representations of the bootstrapping circuitry of FIGS. 2a, 2b, 4, 6a and 6b that are provided here for illustrative purposes. Those of ordinary skill in the art will be aware of suitable circuitry for implementing the various features of the generalised schematic representation of FIGS. 8a-9b, and the operation of such implementations will be apparent from the foregoing description.

The leakage current (Ileak) compensating gain amplifier illustrated in FIGS. 9a and 9b represents gain compensation for the logarithmic function of the back-to-back (or anti-parallel) connected diode arrangement (Back-to-Back Diodes) arrangement of diodes D1 and D2.

FIGS. 1a, 1b, 2a, 2b, 4, 6a and 6b illustrate analog circuitry. However it should be understood that those skilled in the art can readily implement the functionality of these disclosed embodiments using any combination of analog, digital and/or mixed signal (analog and digital) circuitry.

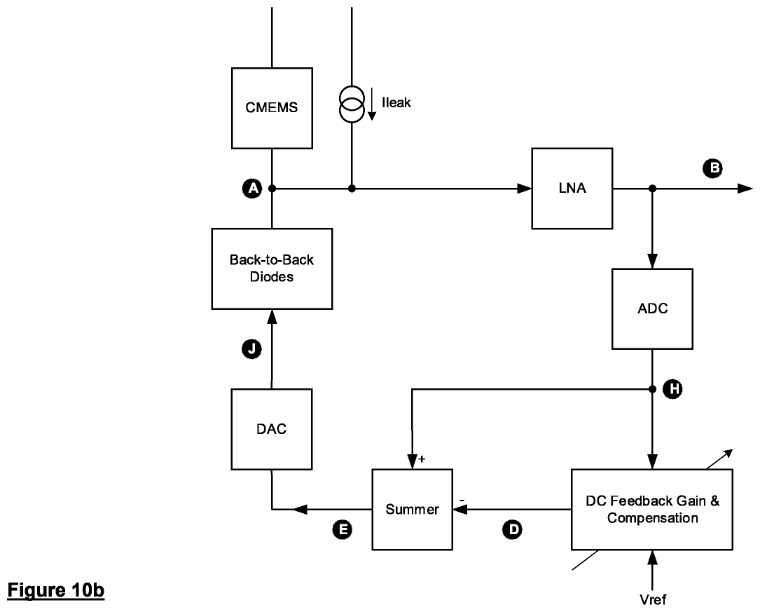

FIGS. 10a and 10a are generalised schematic representations of a mixed-signal (analog and digital) embodiment of the bootstrapping circuitry of FIGS. 2a, 2b, 4, 6a and 6b. Again, those of ordinary skill in the art will be aware of suitable circuitry for implementing the various features of the generalised schematic representation of FIGS. 10a and 10b, and the operation of such implementations will be apparent from the foregoing description.

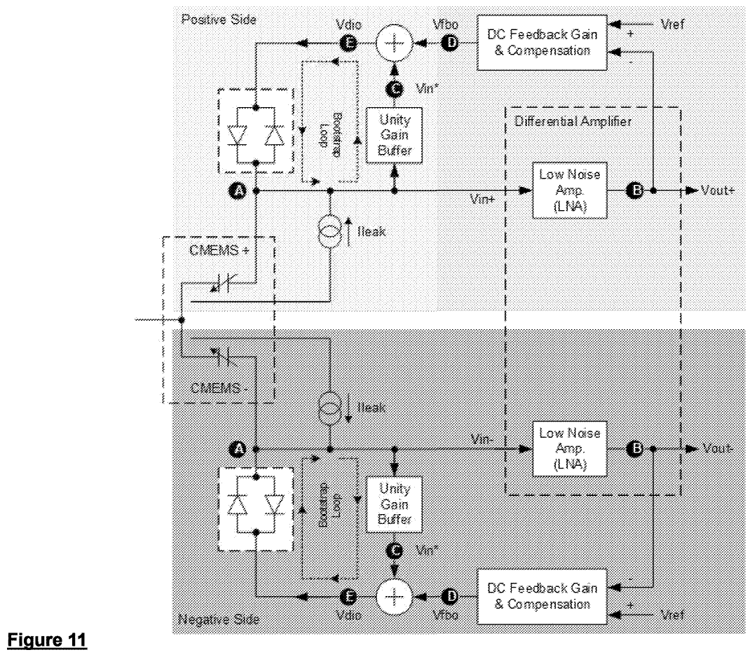

FIG. 11 is a schematic representation of an embodiment of bootstrapping circuitry and amplifier circuitry for a differential capacitive transducer (e.g. a three terminal capacitive transducer such as a three terminal MEMS transducer).

Those of ordinary skill in the art will readily understand from the foregoing description the operation of the bootstrapping circuitry and amplifier circuitry shown in FIG. 11.

Advantages of the embodiments illustrated herein: lower noise; faster settling time of the output voltage Vout (+/−); a relatively wide range of tolerance (in the order of 1 pA) of leakage current (Ileak).

The back-to-back (or anti-parallel) diodes between the output of the unity gain buffer 130 and the first (input) node 112 in FIG. 1 and between the output of the summing circuitry (e.g. 250) and the first (input) node (e.g. 220) in FIGS. 2a, 2b, 4, 6a, 6b, 8a, 8b, 9a, 9b and 11 and between nodes J and A in FIG. 10 have the characteristic that the voltage across them is proportional to the logarithm of the current flowing through them. Such a V-to-logI characteristic may be obtained by other circuitry, such as a diode connected MOS transistor operating in its sub-threshold range, as will be understood by one of ordinary skill in the art, and thus the present disclosure is not limited to the back-to-back (or anti-parallel) connected diode arrangements described and illustrated herein, but also encompasses other circuitry or arrangements of circuit elements that give(s) rise to such a V-to-logI characteristic.

The description above refers to applications which use MEMS transducers, e.g. MEMS microphones, but it will be apparent to those of ordinary skill in the art that the circuitry and techniques described above are equally applicable to any capacitive transducer. Thus the present disclosure is not limited to MEMS microphones or MEMs transducers, but encompasses circuitry for use with any capacitive transducer.

Any of the features of any given aspect or example as herein described and/or illustrated may be combined with any other features of any other aspect or example and the various features described herein may be implemented in any combination in a given example. It should be noted that the above-mentioned embodiments illustrate rather than limit any invention herein contained, and that those skilled in the art will be able to design many alternative embodiments without departing from the scope of the appended feature statements and/or claims. The word “comprising” does not exclude the presence of elements or steps other than those listed in a feature statement and/or claim, “a” or “an” does not exclude a plurality, and a single feature or other unit may fulfil the functions of several units recited in the feature statements and/or claims. Any reference numerals or labels in feature statements and/or claims shall not be construed so as to limit their scope.

As will be understood by those of ordinary skill in the art, the term “circuitry” as herein used may comprise any and all combinations of analogue and/or digital hardware circuit(s), firmware and/or software, including any and all blocks, modules, programs and/or flow diagrams and the like, that could result in the same required output, functionality and/or result. Furthermore, the “circuitry” may also be implemented as, and/or in, an integrated circuit (IC) that may be incorporated in a host device.

Note that as used herein the term module shall be used to refer to a functional unit or block which may be implemented at least partly by dedicated hardware components such as custom defined circuitry and/or at least partly be implemented by one or more software processors or appropriate code running on a suitable general-purpose processor or the like. A module may itself comprise other modules or functional units. A module may be provided by multiple components or sub-modules which need not be co-located and could be provided on different integrated circuits and/or running on different processors.

The term host device is used in this specification to refer to any electronic or electrical device which is removably connectable to an external accessory apparatus. The host device may especially be a portable and/or battery powered host device such as a mobile telephone, an audio player, a video player, a PDA, a mobile computing platform such as a personal computer (PC), laptop computer or tablet and/or a games device for example.

A removable accessory apparatus is any apparatus which may be connected to and used with a host device. The accessory apparatus may, for instance, be a set of headphones, earphones, earbuds or the like, possibly including a microphone, or a headset. The accessory apparatus may also be, for example, line-in and/or line-out devices such as audio/video mixing desks and/or speakers or the like.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions.

Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

The circuitry described above with reference to the accompanying drawings may be incorporated in a host device such as a laptop, notebook, netbook or tablet computer, a gaming device such as a games console or a controller for a games console, a virtual reality (VR) or augmented reality (AR) device, a mobile telephone, a portable audio player or some other portable device, or may be incorporated in an accessory device for use with a laptop, notebook, netbook or tablet computer, a gaming device, a VR or AR device, a mobile telephone, a portable audio player or other portable device.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog™ or VHDL (Very high speed integrated circuit Hardware Description Language). As the skilled person will appreciate, the code may be distributed between a plurality of coupled components in communication with one another. Where appropriate, the embodiments may also be implemented using code running on a field-(re) programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general purpose processor or the like. A module may itself comprise other modules or functional units. A module may be provided by multiple components or sub-modules which need not be co-located and could be provided on different integrated circuits and/or running on different processors.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

The numbered clauses below describe features of the present disclosure:
1. Bias circuitry for a capacitive transducer comprising: a high impedance element (Rpd) for coupling between one terminal of the capacitive transducer and a reference voltage (Vref); and unity gain circuitry coupled in parallel with at least two back-to-back diodes, wherein, in use of the bias circuitry, one terminal of the coupled unity gain circuitry and the at least two back-to-back diodes is coupled to the one terminal of the capacitive transducer.
2. Bias circuitry according to clause 1, wherein the high impedance element (Rpd) comprises a plurality of series connected diodes.
3. Bias circuitry according to clause 2, wherein the series connected diodes comprise poly diodes.
4. Bias circuitry according to clause 2 or clause 3, wherein the series connected diodes comprise PIN diodes, where a PIN diode is a diode with a wide, undoped intrinsic semiconductor region between a p-type semiconductor and an n-type semiconductor region.
5. Bias circuitry according to any of clauses 1 to 4, wherein the unity gain circuitry is a unity gain buffer.
6. Bias circuitry according to any of the preceding clauses, wherein the capacitive transducer comprises a MEMS transducer.
7. Circuitry for amplifying a signal from a capacitive transducer comprising a bias element (Rpd) for coupling between one terminal of the capacitive transducer and a reference voltage (Vref); an amplifier for coupling to the one terminal of the capacitive transducer; and unity gain circuitry coupled in parallel with at least two back-to-back diodes, wherein, in use of the circuitry, one terminal of the coupled unity gain circuitry and the at least two back-to-back diodes is coupled to the one terminal of the MEMS transducer.
8. Circuitry according to clause 7, wherein in use the unity gain circuitry and the at least two back-to-back diodes provide a positive feedback loop around the one terminal of the capacitive transducer.
9. Circuitry according to clause 7 or clause 8, wherein the capacitive transducer comprises a MEMS transducer.
10. Circuitry for coupling to a capacitive transducer for compensating for a leakage current associated with the capacitive transducer, the circuitry comprising: a unity gain positive feedback loop; and a negative feedback loop, wherein a gain of the negative feedback loop is inversely proportional to the leakage current.
11. Circuitry according to clause 10, wherein the unity gain positive feedback loop comprises a unity gain buffer coupled, in use of the circuitry, to a first terminal of the capacitive transducer.
12. Circuitry according to clause 10 or clause 11, wherein the negative feedback loop comprises a first set of back-to-back coupled diodes for coupling to the first terminal of the capacitive transducer.
13. Circuitry according to any of clauses 10-12, wherein the negative feedback loop comprises: a proportional-integral (PI) controller; and a leakage current compensating amplifier.
14. Circuitry according to clause 13, wherein: the PI controller is configured to receive an output voltage of the circuitry and a reference voltage; and the leakage current compensating amplifier is configured to receive an output signal from the PI controller.
15. Circuitry according to clause 13 or clause 14, further comprising a second set of back-to-back coupled diodes coupled between an input and an output of the leakage current compensating amplifier, wherein a property, characteristic or parameter of the second set of back-to-back coupled diodes is substantially similar to the first set of back-to-back coupled diodes such that, in use of the circuitry, the first and second sets of back-to-back coupled diodes exhibit the same or similar current and impedance values.
16. Circuitry according to any of clauses 13-15, wherein the PI controller comprises an integrator.
17. Circuitry according to any of clauses 13-16, wherein the PI controller has a relatively high DC gain.
18. Circuitry according to any of clauses 13-17, wherein the negative feedback loop comprises a low pass filter coupled between an output node of the circuitry and a first input of the PI controller.
19. Circuitry according to clause 18, wherein a parameter, property or characteristic of the low pass filter is adjustable.
20. Circuitry according to any of clauses 14-19, further comprising a variable resistance coupled between an output of the PI controller and an input of the leakage current compensating amplifier for changing a bandwidth mode of the circuitry between a normal bandwidth mode and a high bandwidth mode.
21. Circuitry according to any of clauses 10-20, wherein the capacitive transducer comprises a MEMS transducer.
22. Circuitry for coupling to a capacitive transducer for compensating for a leakage current associated with the capacitive transducer comprising: a unity gain positive feedback loop comprising a unity gain buffer and back-to-back diodes; and a negative feedback loop comprising an integrator and an amplifier, wherein a gain of the negative feedback loop is inversely proportional to the leakage current.
23. Circuitry according to clause 22, wherein the capacitive transducer comprises a MEMS transducer.

1. Circuitry for coupling to a capacitive transducer for compensating for a leakage current associated with the capacitive transducer, the circuitry comprising:
a unity gain positive feedback loop comprising:
unity gain circuitry having an input coupled to an input node of the circuitry; and
a first set of back-to-back coupled diodes coupled between an output of the unity gain circuitry and the input node; and
a negative feedback loop from an output node of the circuitry to the input node, wherein the negative feedback loop comprises a leakage current compensating amplifier and a second set of back-to-back coupled diodes coupled between an input and an output of the leakage current compensating amplifier, and wherein a property, characteristic or parameter of the second set of back-to-back coupled diodes is substantially similar to the first set of back-to-back coupled diodes such that, in use of the circuitry, the first and second sets of back-to-back coupled diodes exhibit the same or similar current and impedance values.

2. Circuitry according to claim 1, wherein the negative feedback loop further comprises:
a proportional-integral (PI) controller.

3. Circuitry according to claim 2, wherein:
the PI controller is configured to receive an output voltage of the circuitry and a reference voltage; and
the leakage current compensating amplifier is configured to receive an output signal from the PI controller.

4. Circuitry according to claim 2, wherein the PI controller comprises an integrator.

5. Circuitry according to claim 2, wherein the PI controller has a relatively high DC gain.

6. Circuitry according to claim 2, wherein the negative feedback loop comprises a low pass filter coupled between an output node of the circuitry and a first input of the PI controller.

7. Circuitry according to claim 6, wherein a parameter, property or characteristic of the low pass filter is adjustable.

8. Circuitry according to claim 3, further comprising a variable resistance coupled between an output of the PI controller and an input of the leakage current compensating amplifier for changing a bandwidth mode of the circuitry between a normal bandwidth mode and a high bandwidth mode.

9. Circuitry according to claim 1, wherein the capacitive transducer comprises a MEMS transducer.
